(19) United States
(12) Patent Application Publication
(10) Pub. No.: US 2013/0180213 A1
(43) Pub. Date: Jul. 18, 2013

(54) Scanner-Sensitive Metallized Films

(71) Applicants: Rajan Verghese, Pittsford, TX (US); Joseph R. Patry, Penfield, NY (US)

(72) Inventors: Rajan Verghese, Pittsford, TX (US); Joseph R. Patry, Penfield, NY (US)

(73) Assignee: ExxonMobil Oil Corporation, Baytown, TX (US)

(21) Appl. No.: 13/669,496

(22) Filed: Nov. 6, 2012

Related U.S. Application Data
(60) Provisional application No. 61/585,856, filed on Jan. 12, 2012.

(51) Int. Cl. B65D 65/40; B65B 11/00; C23C 16/06; B65D 65/42

(52) U.S. Cl. CPC B65D 65/40; B65D 65/42; B65B 11/00; C23C 16/06
USPC 53/461; 428/457; 428/461; 428/220; 428/35.8; 427/251

(57) ABSTRACT

A metallized scanner-sensitive film having a shiny appearance but capable of being optically scanned, as well as a method of manufacture and method of using in packaging; the film comprising at least one metal-adhering skin layer having a first outside surface and an inside surface; a metal layer deposited onto the outside surface of the skin layer; the film having: an optical density within the range of from 0.50 to 1.60; an oxygen transmission rate (OTR) of less than 60 cm³/m²/24 hours; and a water vapor transmission rate (WVTR) of less than 0.60 g/m²/24 hours.

### CROSS-REFERENCE TO RELATED APPLICATION

This application claims the benefit of and priority to U.S. Ser. No. 61/585,856, filed Jan. 12, 2012, which is incorporated by reference.

### FIELD OF THE INVENTION

The present invention relates to metallized films that are capable of being scanned by optical scanners to detect articles within or behind the film, and more particularly to oriented polypropylene barrier films having a shiny metal appearance but capable of optical scanning for article defects behind the film.

### BACKGROUND OF THE INVENTION

Metallized films are usually metallized to an optical density (“OD”) of at least 2.0 for either appearance or barrier properties to protect a product. At such OD, once the product is packaged in the metallized film, it is difficult to scan the product, such as by an optical scanning device, for either hard contaminates or product breakage with scanning equipment. It would be desirable to utilize scanning equipment to check for these conditions when metallized films are desired.

The inventors have found, that by using a lower OD film having a metal film adhered thereto, the bright metal appearance can still be maintained yet the metal deposition can be thin enough such that the scanning equipment can be utilized to detect hard contaminants or product breakage. Surprisingly, this can be accomplished while still maintaining desirable water vapor and oxygen transmission rates for the film. Furthermore, the film can be made in a highly reproducible and controlled manner.

Related disclosures include U.S. Pat. Nos. 3,674,536; 4,345,005; 4,357,383; 4,508,786; 4,522,887; 4,888,237; 5,153,074; 5,194,318; 5,922,471; 5,958,566; 6,033,786; 6,106,933; 6,190,760; 6,790,524; 6,916,526; 6,773,818; U.S. Patent Application Publication No. 2007/0292682; EP 0787582; WO 2008/033622; and WO 2010/135037.

### SUMMARY OF THE INVENTION

Disclosed herein is a metallized scanner-sensitive film comprising at least one metal-adhering skin layer having a first outside surface and an inside surface; a metal layer deposited onto the outside surface of the skin layer; the film having an optical density within the range of from 0.50 or 0.60 or 0.70 or 0.80 or 0.90 to 1.30 or 1.40 or 1.50 or 1.60; an oxygen transmission rate (OTR) of less than 60 or 50 or 40 or 30 cm³/m²/24 hours; and a water vapor transmission rate (WVTR) of less than 0.60 or 0.50 or 0.40 g/m²/24 hours.

Also disclosed is a process to metallize a film comprising moving a film having a metal-adhering skin layer with an outside surface and an inside surface at a rate relative to a source of metal vapor, the source being at a temperature to convert metal fed thereto to a vapor dispersed thereabove; exposing the outside surface to the metal vapor obtained from the metal vapor source; controlling the rate of metal deposition onto the outside surface by changing the exposure time of the outside surface to the metal vapor, changing the distance between the film and metal vapor source, changing the temperature of the metal vapor source, changing the rate of feed of metal to the metal vapor source, or a combination thereof; and obtaining a partially opaque metallized film having the desired optical density at a value within the range of from 0.50 or 0.60 or 0.70 or 0.80 or 0.90 to 1.30 or 1.40 or 1.50 or 1.60 with a standard deviation of from 0.05 or 0.06 or 0.07 to 0.08 or 0.09 or 0.10.

Also disclosed is a process for packaging an article comprising enclosing one or more articles in a package comprising a multi-layer, metallized film comprising at least one metal-adhering skin layer having an outside surface and an inside surface; and a metal layer deposited onto the outside surface of the skin layer; wherein the film has an optical density within the range of from 0.50 or 0.60 or 0.70 or 0.80 or 0.90 to 1.30 or 1.40 or 1.50 or 1.60; an oxygen transmission rate (OTR) of less than 60 or 50 or 40 or 30 cm³/m²/24 hours; and a water vapor transmission rate (WVTR) of less than 0.60 or 0.50 or 0.40 g/m²/24 hours; optically scanning the package; and determining the suitability of the articles in the package.

### BRIEF DESCRIPTION OF THE DRAWINGS

FIG. 1 is the plot of optical densities for optical scans of a roll of Sample 1 film.

FIG. 2 is the plot of optical densities for optical scans of a roll of Sample 3 film.

FIG. 3 is the plot of optical densities for optical scans of a roll of Sample 4 film.

FIG. 4 is the plot of optical densities for optical scans of a roll of Sample 5 film.

FIG. 5 is the plot of optical densities for optical scans of a roll of Sample 6 film.

### DETAILED DESCRIPTION

The present invention is directed to metallized films that maintain a high degree of aesthetically pleasing “shiny” appearance while maintaining good water vapor and oxygen permeability characteristics, but at the same time allows the manufacturer to optically scan goods that are wrapped inside the film so that the quality of the goods can be determined

Thus, what is provided by the inventors is a metallized scanner-sensitive film comprising at least one metal-adhering skin layer having a first outside surface and an inside surface; and a metal layer deposited onto the outside surface of the skin layer; the film having an optical density within the range of from 0.50 or 0.60 or 0.70 or 0.80 or 0.90 to 1.30 or 1.40 or 1.50 or 1.60; an oxygen transmission rate (OTR) of less than 60 or 50 or 40 or 30 cm³/m²/24 hours; and a water vapor transmission rate (WVTR) of less than 0.60 or 0.50 or 0.40 g/m²/24 hours. The OTR and WVTR are determined as described below. By “outside surface” when referring to the film or film layer, what is meant is the surface that faces away from the core layer. The “inside surface” of a film layer typically faces the core layer may be adhered to the core layer or other intervening layers such as a tie-layer, etc.

As part of the invention, another feature is the actual manufacture of the inventive films. Reproducibility of the films and control in its manufacture are important. Thus, provided is a process to metallize a film comprising moving a film having a metal-adhering skin layer with an outside surface and an inside surface at a rate relative to a source of metal vapor, the source being at a temperature to convert metal fed thereto to a vapor dispersed thereabove; exposing the outside surface to the metal vapor obtained from the metal vapor source; controlling the rate of metal deposition onto the outside surface by changing the rate of movement of the film relative to the metal vapor source (or, stated more generally, changing the exposure time of the outside surface to the metal vapor), changing the distance between the film and metal vapor source, changing the temperature of the metal vapor source, changing the rate of feed of metal to the metal vapor source, or a combination thereof; and obtaining a partially opaque metallized film having the desired optical density at a value within the range of from 0.50 or 0.60 or 0.70 or 0.80 or 0.90 to 1.30 or 1.40 or 1.50 or 1.60 with a standard deviation of from 0.05 or 0.06 or 0.07 to 0.08 or 0.09 or 0.10, the standard deviation determined at the 90% confidence level.

In the preferred embodiment, the films described herein have at least 2 layers, and at least 3 in a more preferred embodiment, and at least 5 layers in a particularly preferred embodiment. The films typically have at least two skin layers that are bound to a tie-layer on one face, and are unbound (face away from the film) on the other face. In certain embodiments, the skin layer(s) can be bound directly to the core, with no tie-layer in between. In certain embodiments, there is a tie-layer between each core layer and each skin layer that are otherwise adjacent to one another in the structure. If each skin layer is labeled “S”, and each core layer labeled “C”, and each tie-layer labeled “T”, then preferable film structures include, but are not limited to, SCS, STC, STCS, STCTS, SSTCTS, STSCTSTS, SSTCCTSS, STSTCCTSTS, STTCTTS, SSSTCTS, SSTCTS, and other such structures. In the films described herein, each individual skin layer may be the same or different, preferably the same, in composition compared to other skin layers in the same film. Also, each core layer may be the same or different, and each tie layer may be the same or different. Thus, for example, the film structures above might be represented by S¹T¹CT²S², S¹S²T¹CT²S¹, etc., wherein “S¹” and “S²” are distinct from one another, meaning that they comprise different materials, and/or the same materials but in different ratios. As described herein, “S¹” might be a metal-adhering skin layer and “S²” might be a “second” skin layer. The same is true for “T¹” and “T²”. Preferably, however, each skin layer, tie-layer, and core layer that makes up a film will have a similar or identical identity, as this type of structure allows the use of only three extruders to melt blend and extrude the materials that form each layer of the film.

As used herein, the term “layer” refers to each of the one or more materials, the same or different, that are secured to one another in the form of a thin sheet or film by any appropriate means such as by an inherent tendency of the materials to adhere to one another, or by inducing the materials to adhere as by a heating, radiative, chemical, or some other appropriate process. The term “layer” is not limited to detectable, discrete materials contacting one another such that a distinct boundary exists between the materials. Preferably however, the materials used to make one layer of a film will be different (i.e., the weight percent of components, the properties of each component, and/or the identity of the components may differ) from the materials used to make an adjacent, and adhering, layer. The term “layer” includes a finished product having a continuum of materials throughout its thickness. The “films” described herein comprise three or more layers, and may comprise 3, 4, 5, or more layers in particular embodiments.

The 3, 4, 5, 6, or more layer film structures (films) may be any desirable thickness, and in certain embodiments have an average thickness within the range of from 20 or 30 or 40 to an upper limit of 50 or 60 or 80 or 100 or 150 or 200 or 500 μm. Thus, an exemplary average thickness is within the range of from 30 to 80 μm.

Preferably, a skin layer which is metallized in accordance with this invention will be only one of two or more distinct polymeric layers, namely a skin layer and a core layer, of typically differing composition or characteristics which make up the film. It is also possible for the multi-layer films of the present invention to comprise two distinct “skin” layers, each of which skin layers has an outermost surface which is not in contact with any other polymeric layer and which at least one of which is available for receiving a layer of metal to be deposited thereon (“metal-adhering skin”). Alternatively, the films herein may comprise two distinct “skin” layers but have only one of those skin layers suitable or desirable for having a metal layer deposed thereon. In that instance, the non-metallized skin layer of the film may be of a composition, or may be treated in a manner, which renders that non-metallized skin layer suitable for receiving printing, lamination, coating, or for heat sealing of the film to itself or to another film or to other kinds of substrates.

The skin layer(s) of the multi-layer polymeric films herein may contain one or more copolymers comprising propylene and butylene, preferably a random propylene-butylene copolymer, and/or one or more terpolymers of ethylene, propylene, and butylene. Such copolymers and terpolymers can be prepared in conventional fashion via metallocene-catalyzed or Ziegler-Natta-catalyzed polymerization of appropriate combinations of monomers. Other desirable materials that can make up the metal-adhering skin layer include those with polar groups such as ethylene vinyl acetate copolymers, ethylene vinyl alcohol (EvOH) polymers, and graft polymers such as maleic anhydride-grafted polyolefins.

The copolymers of propylene and butylene useful in the metal-adhering skin layer(s) of the films of the present invention will generally contain from 4.0 wt % to 12 wt % of butylene, generally 1-butene comonomer. More preferably, these propylene/butylene copolymers will comprise from 4.0 wt % to 8.0 wt % of the C₄ comonomer.

For purposes of this invention, the propylene-butylene copolymers may contain relatively minor amounts, for instance, less than 2 wt %, of higher olefins or other comonomers and still be considered as propylene-butylene copolymers. Thus, higher olefin comonomers such as 1-pentene; 1-hexene; 1-heptene; 4-methyl-1-pentene; and/or 1-octene can be incorporated into the propylene-butylene copolymer component of the skin layer(s). More preferably, these comonomers which are not propylene or butylene may comprise less than 1 wt % of these copolymers.

The propylene-butylene copolymers useful in the metal-adhering skin layer(s) of the films herein will preferably have a melting point within the range of from 110° C. or 120° C. or 130° C. to 155° C. or 160° C. or 165° C.; or in a preferred embodiment within the range of from 125° C. to 155° C. More preferably, the melting point of such copolymers will range from 135° C. to 155° C.

Terpolymers of ethylene, propylene, and butylene may also be used in the skin layer(s) of the films herein. In some embodiments, such terpolymers may be either random or block terpolymers. These terpolymers of ethylene, propylene, and butylene useful in the skin layer(s) of the films of the present invention should, like the propylene/butylene copolymers, generally also contain from 4.0 wt % to 12 wt % of butylene, generally 1-butene comonomer. Again, more preferably these ethylene/propylene/butylene terpolymers will comprise from 4.0 wt % to 8.0 wt % of the C₄ comonomer.

The terpolymers of ethylene, propylene, and butylene useful in the metal-adhering skin layer(s) of the films of the present invention will also generally contain from 0.5 wt % to 2.0 wt % of ethylene comonomer. More preferably, these ethylene/propylene/butylene terpolymers will comprise from 0.5 wt % to 1.5 wt % of the C₂ comonomer.

For purposes of this invention, the ethylene-propylene-butylene terpolymers may contain relatively minor amounts, for instance, less than 2 wt %, of higher olefins or other comonomers and still be considered as ethylene-propylene-butylene terpolymers. Thus, higher olefin comonomers such as 1-pentene; 1-hexene; 1-heptene; 4-methyl-1-pentene; and/or 1-octene can be incorporated into the ethylene-propylene-butylene terpolymer component of the skin layer(s). More preferably, these comonomers which are not ethylene, propylene, or butylene will comprise less than 1 wt % of these terpolymers.

The ethylene-propylene-butylene terpolymers useful in the metal-adhering skin layer(s) of the films herein will preferably have a melting point of from 125° C. to 155° C. More preferably, the melting point of such terpolymers will range from 135° C. to 155° C.

The metal-adhering skin layer(s) in the films of the present invention will generally comprise at least 75 wt % of the random propylene-butylene copolymers hereinbefore described, the ethylene-propylene-butylene terpolymers hereinbefore described, or combinations, i.e., blends, of these copolymers and terpolymers. More preferably, the C₃/C₄ copolymers and/or the C₂/C₃/C₄ terpolymers will comprise from 90 wt % to 100 wt % of the skin layer.

The metal-adhering skin layers may also be made up of a mixture of polypropylene, preferably polypropylene homopolymer, and a propylene-α-olefin copolymer. The “propylene-α-olefin elastomers” are polymers comprising from 94 wt % to 75 wt % propylene-derived units and have a melting point below the propylene copolymers described herein. Propylene-α-olefin elastomer typically have a heat of fusion (H_{f}) less than or equal to 75 J/g or 60 J/g or 50 J/g and a triad tacticity of three propylene units, as measured by ¹³C NMR, of 75% or greater, or even 90% or greater. The lowered H_{f} may result from stereo or regio errors and/or from the random incorporation of one or more units derived from an α-olefin comonomer of a C₂ or C₄-C₁₀ α-olefin and optionally diene-derived units. Such propylene-α-olefin elastomer can comprise within the range of from 6 wt % to 12 wt % or 16 wt % or 20 wt % or 25 wt % α-olefin, and more preferably more than 7 wt % α-olefin. Propylene-α-olefin elastomer comprising from 8 wt % to 12 wt % ethylene are particularly suitable.

In particular embodiments, the propylene-α-olefin elastomer have a single peak melting transition as determined by DSC; in certain embodiments, the propylene-α-olefin elastomer has a primary peak melting transition at from less than 90° C., with a broad end-of-melt transition at greater than about 110° C. The peak “melting point” (Tₘ) is defined as the temperature of the greatest heat absorption within the range of melting of the sample. However, the propylene-based elastomer may show secondary melting peaks adjacent to the principal peak, and/or the end-of-melt transition, but for purposes herein, such secondary melting peaks are considered together as a single melting point, with the highest of these peaks being considered the peak melting temperature (Tₘ), or “melting point,” of the propylene-based elastomer. In very particular embodiments, the propylene-α-olefin elastomer have a Tₘ from less than 70° C. or 80° C. or 90° C. or 100° C. or 105° C. in certain embodiments; and within the range of from 10° C. or 15° C. or 20° C. or 25° C. to 65° C. or 75° C. or 80° C. or 95° C. or 105° C. in other embodiments.

Triad tacticity is determined according to the method as disclosed in U.S. Patent Application Publication No. 2004/0236042. The propylene-α-olefin elastomer may have an H_{f} which is greater than or equal to 0.5 J/g and preferably less than or equal to about 50 J/g. The H_{f} is determined using ASTM E-794-95 (version E-794-01). Preferred propylene-α-olefin elastomer have a Mooney viscosity [ML (1+4) @ 125° C.], determined according to ASTM D1646, of less than 100, preferably less than 60, or less than 30 MU. The molecular weight distribution index (Mw/Mn) of the propylene-alpha olefin elastomers may be from 1.8 to 3 or 3.5 or 4 as determined by Gel Permeation Chromatography (GPC). Preferred propylene-α-olefin elastomer are available commercially under the trade names Vistamaxx™ (ExxonMobil Chemical Company, Houston, Tex., USA) and Versify™ (The Dow Chemical Company, Midland, Mich., USA), certain grades of Tafmer™ XM or Notio™ (Mitsui Company, Japan) and certain grades of Softel™ (LyondellBasell Polyolefins of the Netherlands).

The metal-adhering skin layer(s) may also comprise other types of polymeric materials, including homopolymers, other copolymers and other terpolymers, in addition to the copolymers and/or terpolymers discussed previously that are present. Such optional polymeric components of the metal-adhering skin layer(s) herein include polyethylene, polypropylene, and other thermoplastic materials such as polyamides, polyesters, polyvinyls, polylactics, as well as co- and ter-polymers of ethylene and ethylenically unsaturated carboxylic acids. Exemplary optional polymeric components of the skin layer(s) herein may be described in greater detail in the skin layer discussion set forth in U.S. Pat. No. 6,773,818. Though not often preferred, the skin layer may also optionally contain other particulate components if desired, such as fillers, pigments, antiblocks, other agents that might produce a desired surface effect on the metallized skin layer, such as a matte-like metallized surface.

As indicated, the metallized films herein will typically comprise, in addition to one or two metallized skin layers, other layers including a core layer and second skin layer (on the opposite side of the film from the skin layer which is metallized), and may further comprise intermediate or tie-layers. This second skin layer may be either a metallized skin layer or a non-metallized skin layer. The metallized film may also be laminated to other polymeric substrates such as other films, or to non-polymeric substrates such as foil or paper, either before or after metallization of the skin layer.

A core layer preferably comprises a film-forming polyolefin, such as, for example, a polypropylene polymer, such as an isotactic propylene homopolymer (iPP), a high crystallinity propylene homopolymer, a propylene co- or terpolymer preferably made up of 90 wt % or more of propylene, high density polyethylene (HDPE), linear low density polyethylene (LLDPE), syndiotactic polypropylene (sPP), high crystallinity polypropylene, or combinations thereof The film-forming polyolefins of the core layer may be Ziegler-Natta-catalyzed or metallocene-catalyzed.

Preferable propylene-based polymers for the core layer may generally have a melting point of greater than or equal to 130° C. and a melt-flow rate (MFR) of from 0.5 to 8 g/10 min, for example, from 1.5 to 5 g/10 min. Specific examples thereof include, but are not limited to, Fina 3371 (commercially available from Total Chemical Company) and PD 4712E1 (commercially available from ExxonMobil Chemical Company). Specific high crystallinity propylene homopolymers which can be used include Adstif™ HA722J and Adstif™ HA612M, marketed by LyondellBasell and Borealis™ HC101BF, marketed by Borealis A/S. The contemplated ethylene polymers may generally have a melt index ranging from 0.5 to 15 g/10 min. Specific examples thereof include, but are not limited to, HDPE M-6211 and HDPE M-6030 from Equistar Chemical Company, and HD-6704.67 from ExxonMobil Chemical Company.

The core layer may be coextruded with at least one skin layer or laminated to the skin layer, but preferably the core layer is coextruded with at least one skin layer, more preferably two skin layers. In preferred embodiments the core layer may also be oriented with the skin layer, either monoaxially or biaxially, either sequentially or simultaneously.

Another typical optional layer for the metallized multi-layer films herein is a second skin layer which is not metallized. Such a non-metallized second skin layer may comprise any of the coextrudable, orientable film-forming resins known in the art, such as vinyl alcohols, for example, ethylene vinyl alcohol (EVOH), and polyethylenes of the very low-density (VLDPE), low-density (LDPE), linear low-density (LLDPE), medium-density (MDPE), or high-density (HDPE) types. Other suitable film-forming resins for the non-metallized second skin layer include substantially isotactic polypropylene, substantially syndiotactic polypropylene, copolymers of propylene with ethylene and/or an α-olefin having from 4 to 20 carbon atoms, and terpolymers of propylene with ethylene and/or 1-butene and/or another α-olefin(s). These and other non-metallized second skin layer materials are described in greater detail in the hereinbefore referenced U.S. Pat. No. 6,773,818. The second skin layer may also provide functional benefits to the film, such as the ability to be laminated to another substrate or film, or for sealability, printability, and/or processability. The second skin layer may also comprise the polymeric components as described suitable for the metal-adhering layer to provide a second barrier layer that may be metallized along with the metal-adhering layer. For example, the second skin layer may comprise a random propylene-butylene copolymer.

Yet another type of optional layer in the metallized multi-layer films herein comprises one or more “tie” or intermediate polymeric layers. These are one or more polymeric layers which may be disposed between the skin layer and the core layer, and/or one or more layers which may be disposed between a metallized or non-metallized second skin layer and the core layer. A tie-layer of the present film structure may comprise any of the materials disclosed hereinbefore in reference to the metallized skin layer(s), non-metallized second skin layer, or core layer.

In particular embodiments, a tie-layer will be chosen to maximize compatibility with the skin layer thereon, to improve film sealability, and/or to maximize adhesion between said skin layer(s), core layer, and/or other tie-layers. For example, if a non-metallized second skin layer comprises, for example, ethylene vinyl alcohol (EVOH), a tie-layer comprising a maleic anhydride-grafted or modified polymer may preferably be disposed between the second skin layer and the core layer. The tie or intermediate layers may also have the same polymeric make-up as an adjacent layer but may be compositionally distinct by virtue of being free of, or containing different concentrations of, other optional film components (discussed hereinafter) such as cavitating agents or pigments.

The metallized multi-layer films herein may also contain a wide variety of additional optional components which serve to alter film properties, performance, function, or processability. Such optional components include, for example, cavitating agents which create void spaces, and hence opacity, in the film upon orientation of the film. Other conventional film components which can optionally be utilized include pigments, colorants or opacifying agents such as iron oxide, titanium dioxide, and the like; anti-blocking, anti-slip, and anti-static agents such as waxes, fillers, barrier additives, antioxidants, and the like. Such optional film components can be employed in conventional concentrations for their intended function and used in the manner described in the herein before referenced U.S. Pat. No. 6,773,818.

After the one or both skin layers to be metallized have been subjected to appropriate surface treatment, generally in accordance with the process of this invention, the multi-layer films herein will have deposited on at least one of the skin layers having the requisite composition as described herein a thin layer comprising an elemental metal component. The outer surface(s) of the skin layer(s) may be metallized such as by vacuum deposition, or any other metallization technique, such as electroplating or sputtering. The metal is preferably aluminum, but may be any other metal capable of being vacuum deposited, electroplated, or sputtered, such as, for example, gold, zinc, copper, or silver. Techniques for polymeric film metallization are well known. For example, procedures for depositing a metal layer onto a polymeric film layer are described in greater detail in WO 2004/091884.

The extent to which metal is deposited onto a polymeric film layer can be quantified by means of determining the OD of the metallized film. Optical density is a unitless measure of the transmittance of visual light by a film being tested and is determined by standard techniques. A densitometer directs a unidirectional, perpendicular light beam onto the film sample. The light that is transmitted through the film is collected, measured, and logarithmically amplified. The densitometer calculates and displays an OD value.

To determine OD, a commercial densitometer may be used, such as a Macbeth Model TD 932, Tobias Densitometer Model TDX, or Macbeth Model TD903. The densitometer is set to zero with no film specimen. A metallized film specimen is placed over the aperture plate of the densitometer with the test surface facing upwards. The probe arm is pressed down and the resulting OD value is recorded.

Metal layer(s) may be deposited onto the metallized skin layers of the films herein to the extent that the film exhibits an OD of less than 1.60 or 1.50 or 1.40 or 1.30. More preferably, the metallized films herein may exhibit an OD within the range of from 0.50 or 0.60 or 0.70 or 0.80 or 0.90 to 1.30 or 1.40 or 1.50 or 1.60.

The tenacity with which deposited metal layers adhere to the skin layer(s) of the inventive films is determined primarily by skin layer characteristics, but secondarily by application conditions. Such characteristics are, in turn, determined by both the compositional make-up of the skin layer(s) of the films as well as by the surface properties of such skin layer(s).

The tenacity of metal adhesion in the films herein can be quantified by means of measuring metal adhesion bond strength. Bond strength may be measured by sealing a film with a Low Temperature Sealing (LTS) coating (for example, Bicor™ MB 668 from ExxonMobil Chemical Company) onto a specimen of the metallized film. A LAKO Heat Sealer is used in accordance with LAKO test method SOP-PAL-022 (Manual Tray Method). After these two films are sealed together, 2″×6″ test specimens thereof are peeled apart on an Instron dynamometer using the “Seal Strength” program. A peel rate of 12 inches/minute and 180 degrees peel angle is used. The average peel force measured by the Instron may be expressed as grams/inch or grams/25.4 mm, wherein “/inch” means per inch of width of the sealed specimen, measured perpendicular to the direction of force.

The multi-layer films of the present invention will have a metal adhesion bond strength which ranges from at least 100 grams/25 mm, and preferably from 100 grams/25 mm to 300 grams/25 mm. More preferably, the films herein will have a metal adhesion bond strength ranging from 200 to 300 grams/25 mm. Bond strengths in excess of 300 gm/25 mm may be obtained for some combinations of skin layer polymeric composition and treating conditions, though such embodiments may be cost prohibitive for many applications.

In accordance with the present invention, multi-layer metallized films having the requisite metal adhesion bond strength are realized by preparing the films in a manner such that the skin layer(s) to be metallized have desirable surface characteristics prior to metallization. Films having the requisite metal adhesion bond strength characteristics are, in one embodiment, films having low molecular weight oxidized materials which are formed on the skin layer surface prior to metallization. The surface of the film may be altered by having such low molecular weight oxidized materials by virtue of the effects of common film treatment procedures prior to metallization, such as corona discharge treatment, flame treatment, and/or plasma treatment. If too high a proportion of these low molecular weight oxidized materials are not well-anchored to the skin layer surface, such relatively easily removable oxygen-containing materials may adversely influence adhesion of the metal layer subsequently deposited onto the pretreated skin layer surface.

The proportion of the problematic, relatively easily removed, low molecular weight, oxidized materials in relation to the total amount of oxidized materials present at or near the film surface is referred to herein as the “labile oxygen ratio” at the film surface. Labile oxygen ratio is determined by measuring percent of oxygen at the skin layer surface, both before and after solvent washing, using X-ray photoelectron spectroscopy (XPS) and determining from such measurements the relative amounts of before and after oxygen which is present. The film surface may be considered that portion of the film that is influenced by the treatment, including primarily the actual film surface but secondarily that portion of the skin layer that is close enough to the surface to influence metal layer adhesion, such as through molecular attraction or bonding.

The preferred labile oxygen test for determining this parameter in connection with the present invention is set forth as follows: XPS measurements are obtained on a Physical Electronics, Inc., (PHI), model 5600, ESCA spectrometer, using a monochromatic “A1” source (A1 Kα radiation at 1486.6 eV (electron-volts)) and a take-off angle of 45°. Spectra are referenced with respect to the carbon is calibration level of 285.0 eV for the carbons in hydrocarbons. From the XPS spectra obtained, the Carbon, Oxygen, and Nitrogen atomic percentage is measured.

The multi-layer, metallized films prepared in accordance with the present invention, in addition to having desirably high metal adhesion characteristics, will generally also exhibit barrier properties which render such films suitable for use in packaging wherein such barrier properties are especially useful. Packaging utility of this type includes packaging suitable for food products wherein resistance of the films to permeability of both water vapor and oxygen (air) becomes important.

Preferably, the multi-layer metallized films herein will exhibit an Oxygen Transmission Rate (OTR) within the range of less than 60 or 50 or 40 or 30 cm³/m²/24 hours. More preferably, the films herein will have an OTR within the range of from 20 or 30 to 50 or 60 or 70 cm³/m²/24 hours. Oxygen Transmission Rate is a standard parameter used to quantify certain barrier properties of polymeric films. For purposes of this invention, Oxygen Transmission Rate is determined in accordance with ASTM D 3985 at 73° F. (23° C.) and 0% relative humidity (RH).

Preferably, also, the multi-layer metallized films herein will exhibit a Water Vapor Transmission Rate (WVTR) of less than 0.60 or 0.50 or 0.40 g/m²/24 hours. More preferably, the films herein will have a WVTR within the range of from 0.20 or 0.40 to 0.60 or 0.80 g/m²/24 hours. Water Vapor Transmission Rate is also a standard parameter used to quantify certain barrier properties of polymeric films. For purposes of this invention, Water Vapor Transmission Rate is determined in accordance with ASTM F 1249 at 100° F. (37.8° C.) and 90% relative humidity (RH).

A coating may optionally be applied to one or both outer surfaces of the film, preferably after metallization. This includes the outer surface of the core layer if a second skin layer is not present, the outer surface of the second skin layer, and the metallized surface of the metal-adhering layer. The coating may serve to enhance barrier properties, printability, processability, or other performance or aesthetic properties.

The coating may be applied in an amount such that there will be deposited upon drying a smooth, evenly distributed layer that is sufficient to further enhance the, for example, sealability and/or barrier characteristics of the final product. For example, the coating may be applied in an amount on the order of from 0.01 to 0.2 mil thickness, which may be roughly equivalent to 0.2 to 3.5 grams per 1000 sq. in. of film. Alternatively, the coating may be present in an amount of from 1 wt % to 25 wt %, preferably 7 wt % to 15 wt %, based on the weight of the entire film. The coating on the film may be subsequently dried by hot air, radiant heat, or by any other convenient means.

Prior to the application of the coating, the film surface to be coated may be surface-treated or primed with a primer layer. An appropriate primer includes, but is not limited to, a poly(ethyleneimine) primer, modified poly(ethyleneimine) such as with acetylacetonate or methylmethacrylate, and an epoxy primer.

The film may also optionally be laminated to a substrate at one or both of its outer surfaces, again including the outer surface of the core layer if a second skin layer is not present, the outer surface of the second skin layer, and the metallized surface of the metal-adhering layer. For example, the outer surface of the metal-adhering layer may be metallized and subsequently laminated to a protective substrate. Laminating the outer surface(s) may, for many applications including packaging, labeling, or imaging applications, serve to complete the structure necessary for the given application.

Examples of substrates that may be employed include, but are not limited to: a separate polymer film; a metal foil, such as aluminum foil; cellulosic webs, for example, numerous varieties of paper such as corrugated paperboard, kraft paper, glassine, and cartonboard; nonwoven tissue, for example, spunbonded polyolefin fiber and melt-blown microfibers; a metallizing layer; etc.

According to a preferred embodiment of the present invention, the outer surface of the metal-adhering layer is metallized and then the metallized film is laminated to a polymer film, for example, a monolayer or multi-layer polymer film. The film laminated to the outer surface of the inventive film may include a slip surface, a seal surface, a printed surface, or a combination thereof. In a particular embodiment, the film is fully made (all layers laminated together) then the multi-layer film is metallized.

For especially rigorous processes of converting the present film into a commercial wrapping for an article, the metallized metal-adhering layer and/or the, for example, printed second skin layer, are protected via lamination, such that the metallized layer and/or printed layer end up on the inside of a multi-layer film structure.

The outer surface(s) of the metallized multi-layer films herein may be laminated to the substrate by employing a suitable adhesive, for example, a hot melt adhesive such as low density polyethylene or ethylene-methacrylate copolymer; water-based adhesives such as polyvinylidene chloride latex; solvent-based adhesives; or solventless polyethers made from two components, for example, a polyether diol and a polyester diisocyanate.

Alternatively, the lamination may be accomplished via extrusion lamination using, for example, an extruded polyethylene or ethylene co- or terpolymer. In certain embodiments, the outer surface may be laminated to a substrate via heat lamination, which uses heat and pressure to apply a lamination film onto a substrate and improves the durability of the substrate without the need for more expensive water-based lamination or less-desired solvent-based lamination.

In general, the metallized, multi-layer films herein may be prepared by providing a polymeric film comprising at least a skin layer of the requisite polymeric composition, subjecting the outermost surface of the skin layer of the film to plasma-treating conditions which are effective to provide the requisite labile oxygen ratio at the film surface, and then metallizing the plasma-treated surface of the skin layer to form the desired metallized multi-layer film. The film which is first provided preferably has one or more polymeric layers in addition to the skin layer. This film is also preferably oriented, more preferably biaxially oriented, prior to plasma treatment.

One method of making the preferred metallized oriented multi-layer films herein comprises coextruding a melt of the requisite thermoplastic polymers through a die preferably a multi-polymeric-layer melt including at least a skin layer and a core layer, then cooling, for example, by quenching, the multi-layer melt to form a multi-layer sheet. The multi-layer sheet is then stretched in the machine direction (MD) over a series of heated rollers traveling at a progressively increasing differential speed to form an MD oriented multi-layer film. Further stretching of the MD oriented multi-layer film may then take place in the transverse direction (TD) in a heated tenter frame to form a biaxially oriented multi-layer film. Alternatively, MD and TD orientation may be performed in the reverse order or simultaneously.

Preliminary surface treating may then be performed on the orientation apparatus on the metal-adhering layer, core, and/or the second skin layer (if present) of the biaxially oriented multi-layer film with treatment which may preferably include, for example, corona treatment or flame treatment. The film will then be sent to a vacuum metallizing chamber which may also contain plasma or flame treating apparatus wherein the skin layer is subjected to treating conditions sufficient to create the requisite labile oxygen ratio at the skin layer surface. Then the treated skin layer is metallized in the vacuum metallizing chamber to form the desired metallized biaxially oriented multi-layer film.

The treatment step in the film preparation generally serves to impart to the treated skin layer to impart a surface tension level of at least 35 dynes/cm. More preferably, the surface tension of the treated skin layer, prior to metallization, will range from 35 or 38 to 42 or 45 dynes/cm. Surface tension of such treated skin layer surfaces may be measured in accordance with ASTM Standard D2578-84. Due to the inherent difficulty with obtaining repeatable results with measuring surface tension, it is anticipated that the stated range should be observed over a statistically meaningful number of samples and measurements to determine an average value that is at least 35 dynes/cm. Also, before metallizing, the dynamic contact angle may be measured in addition to or instead of the surface tension. The contact angle can be measured using a Cahn DCA 300 tensiometer.

In any case, the metallizing chamber can be of any desirable configuration to cause a thin film of metal to adhere to the film within the chamber. The process of metallizing entails at least the steps of moving a film having a metal-adhering skin layer with an outside surface and an inside surface at a rate relative to a source of metal vapor, the source being at a temperature to convert metal fed thereto to a vapor dispersed thereabove; then exposing the outside surface to the metal vapor obtained from the metal vapor source, where the rate of metal deposition is controlled by changing the exposure time of the outside surface to the metal vapor, changing the distance between the film and metal vapor source, changing the temperature of the metal vapor source, changing the rate of feed of metal to the metal vapor source, or a combination thereof The exposure time of the film can be adjusted by, for example, changing the rate at which the film passes near and/or within the metal vapor generation point(s), such as the boats used to create molten aluminum and a vapor thereabove. Finally a partially opaque, or “scanner-sensitive,” metallized film can be obtained having the desired optical density at a value within the range of from 0.50 to 1.60, and other intermediate ranges in between as discussed herein, with a standard deviation of from 0.05 to 0.10.

In a preferred embodiment, the following process is used to metallize the film. A batch metallizer is an apparatus wherein a roll of polymeric film is loaded into the vacuum chamber having a series of trays or “boats”, preferably placed in a row that encompasses the width of the film to pass through the chamber. After loading and threading up the roll through the winding mechanism on the machine, the chamber is closed and placed under the appropriate vacuum pressure, which can be within the range of from 0.1 or 0.2 or 0.5 or 1 to 6 or 8 or 10 (each value, ×10⁻⁴) millbar (absolute). After the correct vacuum is reached, the intermetallic boats are heated by passing electricity through the boats. The boats are heated to a temperature within the range of from 1000° C. or 1100° C. or 1200° C. to 1500° C. or 1600° C. or 1700° C. in order to melt and vaporize the aluminum. Although aluminum is the preferred metal, other metals can be used and the temperature of the boats adjusted accordingly. The boats are approximately 3 to 5 inches apart in the transverse direction and are approximately 4 to 5 inches below the passing web of film. The film is then fed through the chamber at a rate within the range of from 1 or 2 or 5 to 15 or 20 meters/second. When the boats are at the correct operating temperature, metal wire, preferably aluminum wire, is fed to each boat at a constant feed rate to effectuate the desired level of metallization.

The films described herein are desirably used to package goods (or “articles”) such as food, in particular, candy bars or a plurality of smaller items together. The films can be used to package or “wrap” the goods in any number of ways. Preferably, process for packaging an article might include enclosing one or more articles in a package comprising a multi-layer, metallized film comprising at least one metal-adhering skin layer having an outside surface and an inside surface; and a metal layer deposited onto the outside surface of the skin layer; the film as described above; optically scanning the package; and determining the suitability of the articles in the package.

### EXAMPLES

Six 3-layer co-extruded film samples were produced and biaxially oriented on a tenter frame orienter and in some instances were pretreated in the orienter. The base film design was as follows: Aluminum coating layer/metal-adhering skin layer/core/outside skin layer, in a ratio of 2/44/4 gauge. The base film was flame treated on the metal-adhering side (prior to metallizing) and corona treated on the outside or “second” skin (Ampacet) side.

The materials that made up the film samples have the following basic structure: The metal-adhering skin layer was made from Clyrell™ RC 1601 (Melting Point (DSC) 150° C.) or Clyrell 3C30FHP propylene-butylene copolymers from LyondellBasell and was flame treated (“outside surface”). The core layer was propylene homopolymer (MFR of 2.8 g/10 min [ASTM D1238, 230° C./2.16 kg]; MD 1% Secant Modulus of 10,400 psi; TD 1% Secant Modulus of 7470 psi ASTM D882). The skin layer adjacent to the core opposite the metal-adhering skin layer was masterbatch blend of a C₂/C₃/C₄ terpolymer, polypropylene, and HDPE, and was corona treated on the outside face (opposite the face contacting the core) of this layer. The total film gauge was about 12.7 μm, of which the core layer represents about 88% of the total film thickness and the skin and sealant layers each represent 4% and 8%, respectively, of the total film thickness.

Before metallizing, the dynamic contact angle was measured on some of the base films using a Cahn DCA 300 tensiometer. This unit was used to characterize surface wet-ability of plastic films by measuring, advancing, and receding contact angle. The measure of treatment can be reported in Cos of contact angle using the Cahn Instrument. The two sided treated base film (before metallizing) was a standard base film. The experiments were performed on a 15 micron. The metal-adhering skin tests at 0.81 on average. The non-metallized skin tests at 0.82 on average; it could range from 0.70 to 0.94.

Tests on the OD of the metallized films were performed on the metallizer. The experiment was performed on a batch metallizer. After loading and threading up the roll through the winding mechanism on the machine, the chamber was closed and placed under the appropriate vacuum. After the desired vacuum was reached, about 5×10⁻⁴ mbar, the intermetallic boats are heated by passing electricity through the boats. The boats are heated to about 1450° C. in order to melt and vaporize the aluminum. The boats are approximately 4 inches apart in the transverse direction and are approximately 4 to 5 inches below the passing web of film. The web of film was traveling at a rate of about 10 m/s. When the boats are at correct operating temperature, aluminum wire was fed to each boat at a constant feed rate. The infrared heat of the boat melts the aluminum wire and a pool of molten aluminum collects on the boat. Subsequently, the heat from the boat vaporizes the molten aluminum and the vapor rises and condenses on the moving web when the operator opens the shutter above the boats. Opening the shutter exposes the fast moving web to the aluminum vapor. During the metallizing process, the film roll was unwound and aluminum metal was evaporated onto the passing film. After the metal was condensed on the film, the film passes through an “in-line” optical density scanner. After this in-line check, the film was wound into a roll. The metallizer ran until the base roll was almost completely unwound and processed, then the shutter closed and the web transport stopped and in turn the aluminum wire feed was stopped along with the electric power to the boats. After shutdown, the vacuum was broken and the metallizer was opened and the metallized roll was removed.

The six samples were metallized, three series for each sample. Between runs, when adjustment of the amount of aluminum deposited on the film was desired, the shutter above the boats was closed such that no metal was deposited on the film. This step was performed near the end of a standard roll. The amount of aluminum feed to each boat was then lowered. The metallization was resumed by opening the shutter, and the inline OD target was checked to see if the desired lower OD target was made. If needed the wire feed/boat conditions (rate of aluminum wire feed, voltage, etc.) were adjusted to optimize aluminum deposition on the polymeric film. After the film roll was complete, a sample of the film with the lower OD was taken. Several sheets of the film were checked with the “offline” OD tester, measuring every 2 inches in the transverse direction. Also, the boat spacing was approximately every 4 inches, thus allowing monitoring of the OD between the boats. If needed, the aluminum wire feed was raised or lowered on the next film roll, in order to get the desired “overall” result on the offline unit.

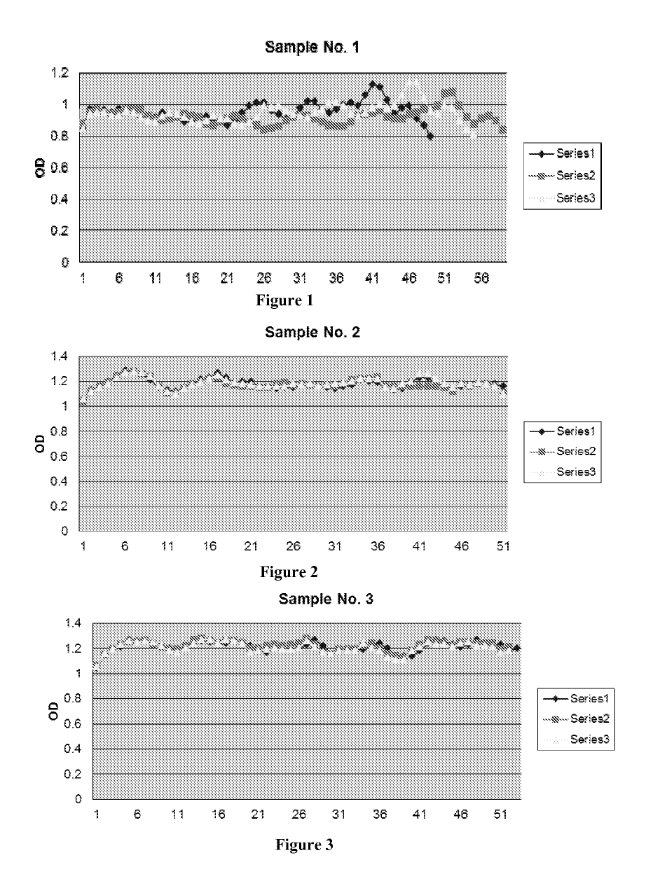

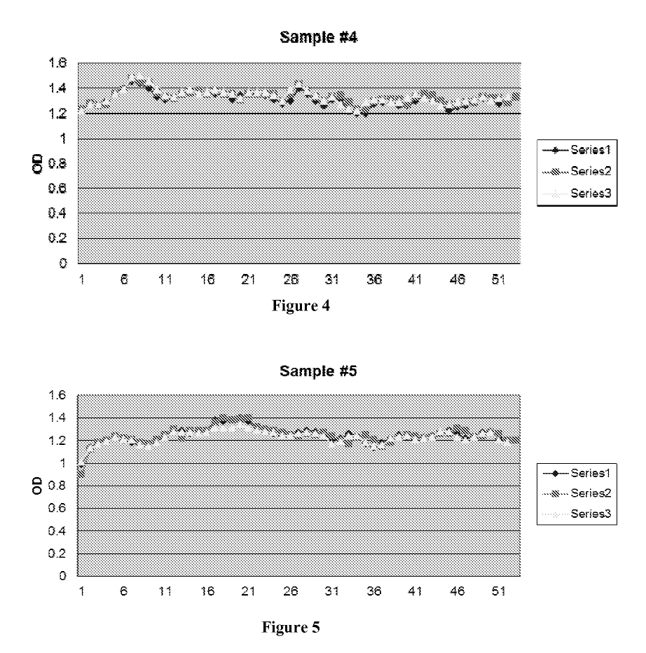

Six samples were made this way on six separate base rolls. The first roll data (first run) was not included in the average as the “offline” target was lower than what was desired. As adjustments were made to the wire feed rate, the OD of the film changed incrementally. The stability of such a process is shown graphically in FIGS. 1 to 5. After completion of this exercise, the “off-line” data was tabulated and statistically analyzed to determine process capability.

Samples were compared at the lower OD range (1.0 OD) and judged the “metal appearance” relative to typical commercial metallized film. It was desired to have good “shiny” metal appearance (comparable to standard commercial film), avoiding “smoky looking” metallized film that occurs in the low range of metal deposition (0.2 to 0.3 OD).

To determine the OD of the films, a commercial densitometer may be used, such as a Macbeth Model TD 932, Tobias Densitometer Model TDX, or Macbeth Model TD903. The densitometer was set to zero with no film specimen. A metallized film specimen was placed over the aperture plate of the densitometer with the test surface facing upwards. The probe arm was pressed down and the resulting OD value was recorded.

Optical density correlates with the amount of aluminum that is placed on the web. For example, in Table 1 are some OD numbers and percent light transmitted.

TABLE 1

| Optical Density | % light transmitted |
|---|---|
| 1.0 | 10 |
| 2.0 | 1 |
| 3.0 | 0.1 |

Thus, an OD of 1.2 would correlate to transmitting 6.3% of the incident light. The higher the OD the less light goes through because of the corresponding increase in aluminum thickness. Optical Density is a log function of light transmittance and is defined as OD (unitless)=Logic₁₀(100/% light transmitted).

Table 2 and FIGS. 1-5 refer to OD tests on 6 film samples as described above. Six samples of films were tested with varying amounts of aluminum deposition, 5 of which are depicted in the figures; Sample 2 data is now shown in the figures due to larger variations in the aluminum deposition due to a power failure of one of the boats. A series of three OD measurements were taken on each role of film at different locations on the film. The purpose of the tests were to demonstrate the useful range of ODs that can be achieved by the invention, as well as the reproducibility (standard deviation, SD, 90 percentile) of the method to produce film to a certain desired specification. The results of water vapor and oxygen transmission rate measurements of the film samples are in Table 3. It is desired to keep the OD below a maximum value but also maintain a minimum OD that still retains good shiny metal appearance. In order to determine whether this was commercially possible, several tests were run on a commercial metallizer to determine: (a) process capability around a target OD; and (b) determine the minimum metal deposition needed (and subsequent OD) to maintain good metal appearance. The results of these tests are shown in Table 2 and FIGS. 1-5.

The Oxygen Transmission Rate (OTR) and the Water Vapor Transmission Rate (WVTR) of the metallized films were measured and recorded in Table 3. Oxygen Transmission Rate is determined in accordance with ASTM D 3985 at 73° F. (23° C.) and 0% relative humidity (RH). Water Vapor Transmission Rate is determined in accordance with ASTM F 1249 at 100° F. (37.8° C.) and 90% relative humidity (RH).

TABLE 2
Summary of data in FIGS. 1-5

| Sample | | | |
|---|---|---|---|
| (Series) | AVG | SD | N |
| 1 (1) | 0.955 | 0.061 | 49 |
| 1 (2) | 0.922 | 0.047 | 59 |
| 1 (3) | 0.947 | 0.061 | 55 |
| | 0.94 | 0.058 | 163 |
| 2 (1) | 1.18 | 0.044 | 51 |
| 2 (2) | 1.175 | 0.043 | 51 |
| 2 (3) | 1.183 | 0.045 | 51 |
| | 1.179 | 0.044 | 153 |
| 3 (1) | 1.213 | 0.043 | 53 |
| 3 (2) | 1.218 | 0.042 | 52 |
| 3 (3) | 1.205 | 0.045 | 52 |
| | 1.212 | 0.044 | 157 |
| 4 (1) | 1.313 | 0.056 | 52 |
| 4 (2) | 1.33 | 0.053 | 53 |
| 4 (3) | 1.334 | 0.059 | 52 |
| | 1.326 | 0.057 | 157 |
| 5 (1) | 1.242 | 0.07 | 52 |
| 5 (2) | 1.245 | 0.077 | 53 |
| 5 (3) | 1.23 | 0.057 | 52 |
| | 1.239 | 0.069 | 157 |
| 6 (1) | 1.241 | 0.109 | 53 |
| 6 (2) | 1.235 | 0.088 | 52 |
| 6 (3) | 1.227 | 0.072 | 52 |
| | 1.234 | 0.091 | 157 |

TABLE 3
Properties of the metallized films

| | O₂Transmission Rate | | | 90% WVTR | | | | | |
|---|---|---|---|---|---|---|---|---|---|
| Sample | (cc/100 sq in/day) | | | (g/100 sq in/day) | | | OPTICAL DENSITY | | |
| No. | EAST | CENTER | WEST | EAST | CENTER | WEST | EAST | CENTER | WEST |
| 1 | 67.4 | 50.7 | 47.7 | 0.48 | 0.38 | 0.36 | 0.87 | 0.91 | 1.1 |
| 2 | 44.5 | — | 38.7 | 0.26 | — | 0.33 | 1.14 | — | 1.24 |
| 3 | 94.3 | — | 36.4 | 0.44 | — | 0.37 | 1.21 | — | 1.22 |
| 4 | 62.0 | — | 36.1 | 0.23 | — | 0.28 | 1.23 | — | 1.27 |
| 5 | 60.8 | — | 49.2 | 0.38 | — | 0.36 | 1.21 | — | 1.15 |
| 6 | 99.5 | — | 109.9 | 0.57 | — | 0.56 | 1.11 | — | 1.18 |

Now, having described some of the preferred aspects of the scanner-sensitive films, methods of making and of using them, provided here in numbered embodiments are:
1. A metallized scanner-sensitive film comprising:
   a) at least one metal-adhering skin layer having a first outside surface and an inside surface; and
   b) a metal layer deposited onto the outside surface of the skin layer; the film having:
      i) an optical density within the range of from 0.50 or 0.60 or 0.70 or 0.80 or 0.90 to 1.30 or 1.40 or 1.50 or 1.60;
      ii) an oxygen transmission rate (OTR) of less than 60 or 50 or 40 or 30 cm³/m²/24 hours; and
      iii) a water vapor transmission rate (WVTR) of less than 0.60 or 0.50 or 0.40 g/m²/24 hours.
2. The film of numbered embodiment 1, wherein the metal-adhering skin layer comprises a propylene-butylene copolymer or an ethylene-propylene-butylene terpolymer, said copolymer or terpolymer having a butylene content of from 4 wt % to 12 wt % or 16 wt % or 20 wt %.
3. The film of numbered embodiment 1 or 2, wherein the metal-adhering skin layer comprises a blend of polypropylene and from 5 wt % or 10 wt % or 15 wt % to 20 wt % or 30 wt % or 40 wt % or 45 wt % of a propylene-α-olefin elastomer.
4. The film of any one of the previous numbered embodiments, wherein the metal-adhering skin layer comprises a polymer having a melting point (DSC) within the range of from 110° C. or 120° C. or 130° C. to 155° C. or 160° C. or 165° C.
5. The film of any one of the previous numbered embodiments, wherein the inside surface of the at least one skin layer is adjacent to a core layer comprising polypropylene.
6. The film of claim 1, wherein the first outside surface of the skin layer is chemically, ionically, or heat treated prior to the deposition of the metal layer.
7. The film of claim 5, wherein the film has a second skin layer having an inside surface adjacent to the core layer side that is opposite the metal-adhering skin layer; the second skin layer having an outside surface that is chemically, ionically, or heat treated.
8. The film of any one of the previous numbered embodiments, wherein the film has a thickness within the range of from 8 μm or 10 μm to 18 μm or 20 μm or 30 μm or 40 μm.
9. The film of any one of the previous numbered embodiments, wherein the measured value of the optical density has a standard deviation of from 0.05 or 0.06 or 0.07 to 0.08 or 0.09 or 0.10.
10. A packaged article comprising packaging that includes the film of any one of the previous numbered embodiments.
11. A process to metallize a film comprising:
   a) moving a film having a metal-adhering skin layer with an outside surface and an inside surface at a rate relative to a source of metal vapor, the source being at a temperature to convert metal fed thereto to a vapor dispersed thereabove;
   b) exposing the outside surface to the metal vapor obtained from the metal vapor source;
   c) controlling the rate of metal deposition onto the outside surface by changing the exposure time of the outside surface to the metal vapor, changing the distance between the film and metal vapor source, changing the temperature of the metal vapor source, changing the rate of feed of metal to the metal vapor source, or a combination thereof; and
   d) obtaining a partially opaque metallized film having the desired optical density at a value within the range of from 0.50 to 1.60 with a standard deviation of from 0.05 to 0.10.
12. The process of numbered embodiment 11, wherein the film is an at least three-layer film having a polypropylene core, a metal-adhering skin layer, and a second skin layer.
13. The process of numbered embodiment 11 or 12, wherein the melting point (DSC) of the polymer comprising the metal-adhering skin layer is within the range of from 110° C. or 120° C. or 130° C. to 155° C. or 160° C. or 165° C.
14. The process of any one of the previous numbered embodiments 11-13, wherein the metal-adhering skin layer comprises a propylene-butylene copolymer or an ethylene-propylene-butylene terpolymer, said copolymer or terpolymer having a butylene content of from 4 wt % to 12 wt % or 16 wt % or 20 wt %.
15. The process of any one of the previous numbered embodiments 11-14, wherein the first outside surface of the skin layer is chemically, ionically, or heat treated prior to being exposed to the metal vapor.
16. The process of any one of the previous numbered embodiments 11-15, wherein the film has a second skin layer having a second outside surface that is opposite the first outside surface; wherein the second outside surface is chemically, ionically, or heat treated.
17. The process of any one of the previous numbered embodiments 11-16, wherein the film has an optical density within the range of from 0.80 to 1.30.
18. The process of any one of the previous numbered embodiments 11-17, wherein the target specification for the optical density of the film is 1.10 or 1.20 or 1.30, and making a film at these optical densities with a standard deviation of 0.100 or 0.080 or 0.050 or less.
19. The process of any one of the previous numbered embodiments 11-18, wherein the metallized film has an oxygen transmission rate (OTR) of less than 60 or 50 or 40 or 30 cm³/m²/24 hours; and a water vapor transmission rate (WVTR) of less than 0.60 or 0.50 or 0.40 g/m²/24 hours.
20. A process for packaging an article comprising:
   1) enclosing one or more articles in a package comprising a multi-layer, metallized film comprising the film of any one of the previous numbered embodiments 1 to 10;
   2) optically scanning the package; and
   3) determining the suitability of the articles in the package.

Also provided is the use of a film in packaging an article, the film having the features of any one of the previous numbered embodiments 1 to 10.

Also provided is the use of an optical scanning device for scanning articles contained, or wrapped within, a film having the features of any one of the previous numbered embodiments 1 to 10.

Also provided is the use of an optical scanning device for scanning articles contained, or wrapped within, a film made by the process of any one of the previous numbered embodiments 11 to 19.

1. A metallized scanner-sensitive film comprising:
a) at least one metal-adhering skin layer having a first outside surface and an inside surface; and
b) a metal layer deposited onto the outside surface of the skin layer;
the film having:
i) an optical density within the range of from 0.50 to 1.60;
ii) an oxygen transmission rate (OTR) of less than 60 cm³/m²/24 hours; and
iii) a water vapor transmission rate (WVTR) of less than 0.60 g/m²/24 hours.

2. The film of claim 1, wherein the metal-adhering skin layer comprises a propylene-butylene copolymer or an ethylene-propylene-butylene terpolymer, said copolymer or terpolymer having a butylene content of from 4 wt % to 12 wt % or 16 wt % or 20 wt %.

3. The film of claim 1, wherein the metal-adhering skin layer comprises a blend of polypropylene and from 5 wt % to 45 wt % of a propylene-α-olefin elastomer.

4. The film of claim 1, wherein the metal-adhering skin layer comprises a polymer having a melting point (DSC) within the range of from 110° C. to 165° C.

5. The film of claim 1, wherein the inside surface of the at least one skin layer is adjacent to a core layer comprising polypropylene.

6. The film of claim 1, wherein the first outside surface of the skin layer is chemically, ionically, or heat treated prior to the deposition of the metal layer.

7. The film of claim 5, wherein the film has a second skin layer having an inside surface adjacent to the core layer side that is opposite the metal-adhering skin layer; the second skin layer having an outside surface that is chemically, ionically, or heat treated.

8. The film of claim 1, wherein the film has a thickness within the range of from 8 μm to 40 μm.

9. The film of claim 1, wherein the measured value of the optical density has a standard deviation of from 0.05 to 0.10.

10. A packaged article comprising packaging that includes the film of claim 1.

11. A process to metallize a film comprising:
a) moving a film having a metal-adhering skin layer with an outside surface and an inside surface at a rate relative to a source of metal vapor, the source being at a temperature to convert metal fed thereto to a vapor dispersed thereabove;
b) exposing the outside surface to the metal vapor obtained from the metal vapor source;
c) controlling the rate of metal deposition onto the outside surface by changing the exposure time of the outside surface to the metal vapor, changing the distance between the film and metal vapor source, changing the temperature of the metal vapor source, changing the rate of feed of metal to the metal vapor source, or a combination thereof; and
d) obtaining a partially opaque metallized film having the desired optical density at a value within the range of from 0.50 to 1.60 with a standard deviation of from 0.05 to 0.10.

12. The process of claim 11, wherein the film is an at least three-layer film having a polypropylene core, a metal-adhering skin layer, and a second skin layer.

13. The process of claim 11, wherein the melting point (DSC) of the polymer comprising the metal-adhering skin layer is within the range of from 110° C. to 165° C.

14. The process of claim 11, wherein the metal-adhering skin layer comprises a propylene-butylene copolymer or an ethylene-propylene-butylene terpolymer, said copolymer or terpolymer having a butylene content of from 4 wt % to 20 wt %.

15. The process of claim 11, wherein the first outside surface of the skin layer is chemically, ionically, or heat treated prior to being exposed to the metal vapor.

16. The process of claim 11, wherein the film has a second skin layer having a second outside surface that is opposite the first outside surface; wherein the second outside surface is chemically, ionically, or heat treated.

17. The process of claim 11, wherein the film has an optical density within the range of from 0.80 to 1.30.

18. The process of claim 11, wherein the target specification for the optical density of the film is a value within the range from 0.60 to 1.30, and making a film at these optical densities with a standard deviation of 0.100 or less.

19. The process of claim 11, wherein the metallized film has an oxygen transmission rate (OTR) of less than 60 cm³/m²/24 hours; and a water vapor transmission rate (WVTR) of less than 0.60 g/m²/24 hours.

20. A process for packaging an article comprising:
1) enclosing one or more articles in a package comprising a multi-layer, metallized film comprising:
a) at least one metal-adhering skin layer having an outside surface and an inside surface; and
b) a metal layer deposited onto the outside surface of the skin layer;
the film having:
i) an optical density within the range of from 0.50 to 1.60;
ii) an oxygen transmission rate (OTR) of less than 60 cm³/m²/24 hours; and
iii) a water vapor transmission rate (WVTR) of less than 0.60 0.40 g/m²/24 hours;
2) optically scanning the package; and
3) determining the suitability of the articles in the package.

21. The process of claim 20, wherein the film is an at least three-layer film having a polypropylene core, a metal-adhering skin layer, and a second skin layer.

22. The process of claim 20, wherein the metal-adhering skin layer comprises a propylene-butylene copolymer or an ethylene-propylene-butylene terpolymer, said copolymer or terpolymer having a butylene content of from 4 wt % to 20 wt %.

23. The process of claim 20, wherein the metal-adhering skin layer comprises a blend of polypropylene and from 5 wt % to 45 wt % of a propylene-α-olefin elastomer.

24. The process of claim 20, wherein the first outside surface of the skin layer is chemically, ionically, or heat treated prior to being exposed to the metal vapor.

25. The process of claim 20, wherein the film has a second skin layer having a second outside surface that is opposite the first outside surface; wherein the second outside surface is chemically, ionically, or heat treated.
